(19) United States
(12) Patent Application Publication
(10) Pub. No.: US 2025/0233100 A1
(43) Pub. Date: Jul. 17, 2025

(54) SEMICONDUCTOR PACKAGE

(71) Applicant: Samsung Electronics Co., Ltd., Suwon-si (KR)

(72) Inventor: Youn Jo MUN, Suwon-si (KR)

(21) Appl. No.: 18/972,089

(22) Filed: Dec. 6, 2024

(30) Foreign Application Priority Data
Jan. 15, 2024 (KR) 10-2024-0005841

(51) Int. Cl. H01L 23/00

(52) U.S. Cl. CPC H01L 24/49; H01L 24/06; H01L 24/48; H01L 24/45; H01L 2224/04042; H01L 2224/0603; H01L 2224/06179; H01L 2224/45124; H01L 2224/45139; H01L 2224/45144; H01L 2224/45147; H01L 2224/48145; H01L 2224/48227; H01L 2224/48451; H01L 2224/48464; H01L 2224/49179; H01L 2224/4945

(57) ABSTRACT

A semiconductor package is provided. The semiconductor package comprises a package substrate including first and second surfaces opposite to each other in a first direction, a plurality of substrate pads on the second surface, and first and second substrate edges respectively extending in a second direction intersecting the first direction and spaced apart from each other in a third direction intersecting the first and second directions, a first semiconductor chip on the package substrate, including third and fourth surfaces opposite to each other in the first direction, a plurality of chip pads and a plurality of chip dummy pad groups on the fourth surface, and first and second chip edges respectively extending in the second direction and spaced apart from each other in the third direction, and a plurality of first wires, each first wire of the plurality of first wires respectively connecting a respective substrate pad of the plurality of substrate pads with the plurality of chip pads, wherein the first chip edge is disposed to be closer to the first substrate edge than the second substrate edge, the plurality of substrate pads is disposed along the first substrate edge, the plurality of chip pads is disposed along the first chip edge, the first semiconductor chip includes third and fourth chip edges respectively extending in the third direction and spaced apart from each other in the second direction, a first corner formed at the intersection of the first chip edge and the third chip edge, a second corner formed at the intersection of first chip edge and the fourth chip edge, a third corner formed at the intersection of the second chip edge and the fourth chip edge, and a fourth corner formed at the intersection of the second chip edge and the third chip edge, and the plurality of chip dummy pad groups is respectively disposed on at least one of the first to fourth corners.

### CROSS-REFERENCE TO RELATED APPLICATION

This application claims priority from Korean Patent Application No. 10-2024-0005841 filed on Jan. 15, 2024, in the Korean Intellectual Property Office and all the benefits accruing therefrom under 35 U.S.C. 119, the contents of which in its entirety are herein incorporated by reference.

### BACKGROUND

### Technical Field

The present disclosure relates to a semiconductor package, and more particularly, to a semiconductor package and a method of fabricating the same in which performance and reliability of a product are improved by alleviating delamination between a package substrate and a semiconductor chip or between semiconductor chips.

### Description of the Related Art

Semiconductor packages are being developed in a way of efficiently fabricating semiconductor chips having more various functions and high reliability. In addition, in order to package more semiconductor chips in the same area, a stack-type semiconductor package in which a plurality of such semiconductor chips is stacked has been proposed. Meanwhile, in order to fabricate a semiconductor package, a wafer-state semiconductor chip may be divided, and the divided semiconductor chip may be bonded onto a package substrate, and a bonding process using a metal wire may be performed. In this case, a force for bonding the semiconductor chip onto the package substrate may not be sufficiently transferred to a corner portion of the semiconductor chip, whereby a warpage defect of the semiconductor chip may occur. When the degree of such a warpage defect of the semiconductor chip is greater than or equal to a certain level, the semiconductor chip may be delaminated from the package substrate, whereby performance of the semiconductor package may be deteriorated.

### BRIEF SUMMARY

An object of the present disclosure is to provide a semiconductor package with improved product performance and reliability.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a semiconductor package comprising a package substrate including first and second surfaces opposite to each other in a first direction, a plurality of substrate pads on the second surface, and first and second substrate edges respectively extending in a second direction intersecting the first direction and spaced apart from each other in a third direction intersecting the first and second directions, a first semiconductor chip on the package substrate, including third and fourth surfaces opposite to each other in the first direction, a plurality of chip pads and a plurality of chip dummy pad groups on the fourth surface, and first and second chip edges respectively extending in the second direction and spaced apart from each other in the third direction, and a plurality of first wires, each first wire of the plurality of first wires respectively connecting a respective substrate pad of the plurality of substrate pads with a respective chip pad of the plurality of chip pads, wherein the first chip edge is disposed to be closer to the first substrate edge than the second substrate edge, the plurality of substrate pads is disposed along the first substrate edge, each chip pad of the plurality of chip pads is disposed along the first chip edge, the first semiconductor chip includes third and fourth chip edges respectively extending in the third direction and spaced apart from each other in the second direction, a first corner formed at the intersection of the first chip edge and the third chip edge, a second corner formed at the intersection of the first chip edge and the fourth chip edge, a third corner formed at the intersection of the second chip edge and the fourth chip edge, and a fourth corner formed at the intersection of the second chip edge and the third chip edge, and each chip dummy pad group of the plurality of chip dummy pad groups is respectively disposed at one of the first to fourth corners.

According to an aspect of the present disclosure, there is provided a semiconductor package comprising a first semiconductor chip including first and second surfaces opposite to each other in a first direction, a plurality of first chip pads on the second surface, and first and second chip edges respectively extending in a second direction intersecting the first direction and spaced apart from each other in a third direction intersecting the first and second directions, a second semiconductor chip disposed on the first semiconductor chip, including third and fourth surfaces opposite to each other in the first direction, a plurality of second chip pads and a plurality of chip dummy pads on the fourth surface, and third and fourth chip edges respectively extending in the second direction and spaced apart from each other in the third direction, and a plurality of first wires, each first wire of the plurality of first wires respectively connecting a respective first chip pad of respectively connecting a respective first chip pad of the plurality of first chip pads with a respective second chip pad of the plurality of second chip pads, wherein the third chip edge is closer to the first chip edge than the second chip edge, each first chip pad of the plurality of first chip pads is disposed along the first chip edge, each second chip pad of the plurality of second chip pads is disposed along the third chip edge, the second semiconductor chip includes fifth and sixth chip edges respectively extended in the third direction and spaced apart from each other in the second direction, a first corner formed at the intersection of the third chip edge and the fifth chip edge, and a second corner formed at the intersection of the third chip edge and the sixth chip edge, and the plurality of chip dummy pads is disposed on at least one of the first corner or the second corner.

According to an aspect of the present disclosure, there is provided a semiconductor package comprising a package substrate including first and second surfaces opposite to each other in a first direction and a plurality of substrate pads on the second surface, a first semiconductor chip on the package substrate, including third and fourth surfaces opposite to each other in the first direction, and including a plurality of first chip pads and a plurality of first chip dummy pads on the fourth surface, a plurality of first wires with each first wire of the plurality of first wires respectively connecting a substrate pad of the plurality of substrate pads with a respective first chip pad of the plurality of first chip pads, a second semiconductor chip on the first semiconductor chip, including fifth and sixth surfaces opposite to each other in the first direction and a plurality of second chip pads and a plurality of second chip dummy pads on the sixth surface, and a plurality of second wires with each second wire of the plurality of second wires respectively connecting a respective first chip pad of the plurality of first chip pads with a respective second chip pad of the plurality of second chip pads, wherein the first semiconductor chip includes first and second chip edges respectively extending in a second direction intersecting the first direction and spaced apart from each other in a third direction intersecting the first direction and the second direction, third and fourth chip edges respectively extending in the third direction and spaced apart from each other in the second direction, a first corner formed at the intersection of the first chip edge and the third chip edge, a second corner formed at the intersection of the first chip edge and the fourth chip edge, a third corner formed at the intersection of the second chip edge and the fourth chip edge, and a fourth corner formed at the intersection of the second chip edge and the third chip edge, the second semiconductor chip includes fifth and sixth chip edges respectively extending in the second direction and spaced apart from each other in the third direction, seventh and eighth chip edges respectively extended in the third direction and spaced apart from each other in the third direction, a fifth corner formed at the intersection of the fifth chip edge and the seventh chip edge, a sixth corner formed at the intersection of the fifth chip edge and the eighth chip edge, a seventh corner formed at the intersection of the sixth chip edge and the eighth chip edge, and an eighth corner formed at the intersection of the sixth chip edge and the seventh chip edge, each first chip dummy pad of the plurality of first chip dummy pads is disposed at one of the first to fourth corners, and each second chip dummy pad of the plurality of second chip dummy pads is disposed at one of the fifth to eighth corners.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example view illustrating a semiconductor package according to some embodiments.

FIG. 2 is an example cross-sectional view taken along line I-I of FIG. 1.

FIG. 3 is an example cross-sectional view taken along line II-II of FIG. 1.

FIG. 4 is an example cross-sectional view taken along line III-III of FIG. 1.

FIGS. 5 and 6 are example views illustrating a semiconductor package according to some other embodiments.

FIG. 7 is an example view illustrating a semiconductor package according to some other embodiments.

FIGS. 8 and 9 are example views illustrating a semiconductor package according to some other embodiments.

FIGS. 10 and 11 are example views illustrating a semiconductor package according to some other embodiments.

FIGS. 12 and 13 are example views illustrating a semiconductor package according to some other embodiments.

FIGS. 14 and 15 are example views illustrating a semiconductor package according to some other embodiments.

FIG. 16 is an example view illustrating a method of fabricating the semiconductor package of FIGS. 1 to 4.

FIG. 17 is an example view illustrating a method of fabricating the semiconductor package of FIGS. 8 and 9.

FIG. 18 is an example view illustrating a method of fabricating the semiconductor package of FIGS. 10 and 11.

FIG. 19 is an example view illustrating a method of fabricating the semiconductor package of FIGS. 12 and 13.

FIG. 20 is an example view illustrating a method of fabricating the semiconductor package of FIGS. 14 and 15.

FIGS. 21 and 22 are example views illustrating a semiconductor package according to some other embodiments.

FIGS. 23 and 24 are example views illustrating a semiconductor package according to some other embodiments.

### DETAILED DESCRIPTION OF THE DISCLOSURE

Hereinafter, a semiconductor package according to some embodiments will be described with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening clements present at the point of contact. Other words used to describe the relationship between elements should be interpreted in a like fashion (e.g., “between” versus “directly between,” “adjacent” versus “directly adjacent,” etc.).

Items described in the singular herein may be provided in plural, as can be seen, for example, in the drawings. Thus, the description of a single item that is provided in plural should be understood to be applicable to the remaining plurality of items unless context indicates otherwise. Additionally, when describing relationships involving a plurality of items, it will be understood that the relationship may be a one-to-one, one-to-many, many-to-many, and/or many-to-one relationship with the individual items in the plurality, unless other specified.

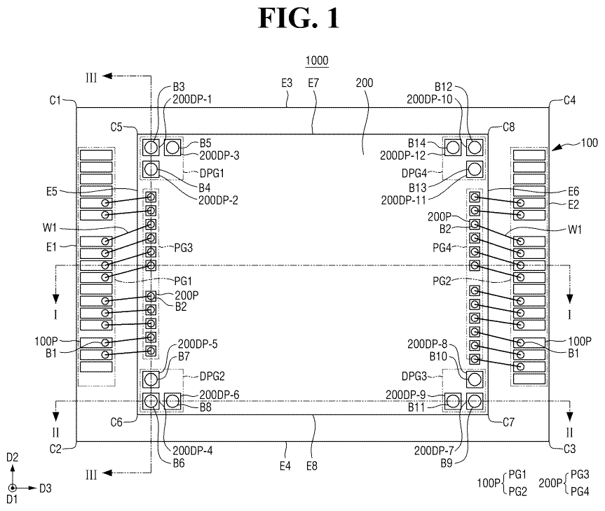

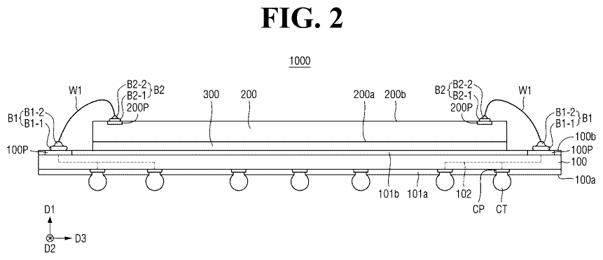

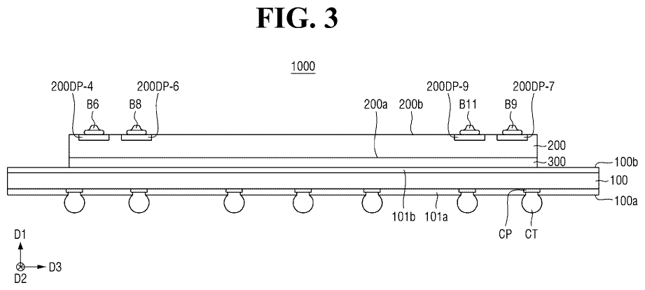

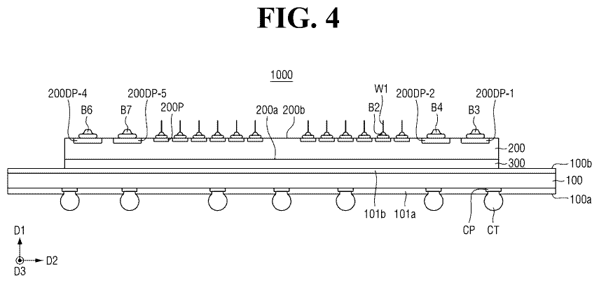

FIG. 1 is an example view illustrating a semiconductor package according to some embodiments. FIG. 2 is an example cross-sectional view taken along line I-I of FIG. 1. FIG. 3 is an example cross-sectional view taken along line II-II of FIG. 1. FIG. 4 is an example cross-sectional view taken along line III-III of FIG. 1. Hereinafter, a semiconductor package according to some embodiments will be described with reference to FIGS. 1 to 4. In the following description, an upper or lower surface and an upper or lower portion may be based on a first direction D1, which may be a vertical direction in the drawings. For example, the upper surface and the upper portion may be in reference to the first direction D1 and indicate a surface or portion at a higher level in the first direction, and the lower surface and the lower portion may be in reference to the first direction D1 and indicate a surface or portion at a lower level in the first direction D1.

The semiconductor package 1000 may include a package substrate 100, a semiconductor chip 200, wires W1, substrate pads 100P, chip pads 200P, chip dummy pads (or dummy chip pads) 200DP-1 to 200DP-12, bump balls B1 to B14, an adhesive layer 300, connection pads CP, and connection terminals CT.

The package substrate 100 may have a plate shape including a lower surface 100a and an upper surface 100b opposite to each other in the first direction D1. The package substrate 100 may include a first substrate edge E1, second substrate edge E2, third substrate edge E3, and fourth substrate edge E4, which may be lateral surfaces of the package substrate 100 extending from the lower surface 100a to the upper surface 100b. Each of the substrate edges E1 and E2 may extend in a second direction D2 intersecting the first direction D1. Also, the substrate edges E1 and E2 may be spaced apart from each other in a third direction D3 intersecting the first direction DI and the second direction D2. Each of the substrate edges E3 and E4 may extend in the third direction D3 and may be spaced apart from each other in the second direction D2.

The package substrate 100 may include a first corner C1 formed at a portion where the first substrate edge E1 and the third substrate edge E3 intersect each other, a second corner C2 formed at a portion where the first substrate edge E1 and the fourth substrate edge E4 intersect each other, a third corner C3 formed at a portion where the second substrate edge E2 and the fourth substrate edge E4 intersect each other, and a fourth corner C4 formed at a portion where the second substrate edge E2 and the third substrate edge E3 intersect each other.

The package substrate 100 may be a printed circuit board (PCB) or a silicon (Si) interposer substrate, but is not limited thereto. When the package substrate 100 is a PCB, the package substrate 100 may be made of at least one material selected from phenolic resin, epoxy resin, or polyimide. The package substrate 100 may include at least one material selected from tetrafunctional epoxy, polyphenylene ether, epoxy/polyphenylene oxide, bismaleimide triazine (BT), thermount, cyanate ester, or liquid crystal polymer. The package substrate 100 may include a resin impregnated in a core material, such as a glass fiber, a glass cloth, or a glass fabric, together with an inorganic filler, for example, a prepreg, an Ajinomoto Build-up Film (ABF), FR-4, or Bismaleimide Triazine (BT).

A lower solder resist layer 101a may be formed on the lower surface 100a of the package substrate 100, and an upper solder resist layer 101b may be formed on the upper surface 100b of the package substrate 100. The lower surface 100a of the package substrate 100 may be covered by the lower solder resist layer 101a, and the upper surface 100b of the package substrate 100 may be covered by the upper solder resist layer 101b. Each of the solder resist layers 101a and 101b may include a photoimageable dielectric material (PID), but is not limited thereto.

The substrate pads 100P may be disposed on the upper surface 100b of the package substrate 100, and the connection pads CP may be disposed on the lower surface 100a of the package substrate 100. The substrate pads 100P may be patterned in the upper solder resist layer 101b, and the connection pads CP may be patterned in the lower solder resist layer 101a. The package substrate 100 may include internal wirings 102 connecting the substrate pads 100P to the connection pads CP. The internal wirings 102 may include a plurality of wiring vias electrically connecting the connection terminal CT with components on the upper surface 100b of the package substrate 100. The internal wirings 102 may include at least one of copper (Cu), aluminum (Al), silver (Ag), tin (Sn), gold (Au), nickel (Ni), lead (Pb), titanium (Ti) or their alloy, but is not limited thereto.

At least one passive element (e.g., a resistor or a capacitor) may be installed inside the package substrate 100 or at a surface (e.g., the upper surface 100b and/or the lower surface 100a) of the package substrate 100. The upper solder resist layer 101b may be formed on the upper surface 100b of the package substrate 100 with an opening to expose the substrate pads 100P. The lower solder resist layer 101a may be formed on the lower surface 100a of the package substrate 100 to expose the connection pads CP.

The connection terminals CT may be formed on the lower surface 100a of the package substrate 100. The connection terminals CT may be attached to lower surfaces of the connection pads CP. The connection terminals CT may electrically connect the internal wirings 102 to an external device (e.g., a module substrate, a system board, etc.). Therefore, the connection terminals CT may provide an electrical signal to the internal wirings 102 or may provide the electrical signal provided from the internal wirings 102 to the external device.

The connection terminals CT may be solder bumps, but are not limited thereto. The connection terminals CT may have various shapes such as a land, a ball, a pin, and a pillar. The number, spacing, and arrangement shape of the connection terminals CT are not limited to the shown examples, and may vary depending on designs. The connection terminals CT may include at least one of tin (Sn), indium (In), lead (Pb), zinc (Zn), nickel (Ni), gold (Au), silver (Ag), copper (Cu), antimony (Sb), bismuth (Bi) or combinations thereof, but are not limited thereto.

The substrate pads 100P may be disposed on the upper surface 100b of the package substrate 100 and may be divided into groups. An example in which the substrate pads 100P are divided into a first substrate pad group PG1 and a second substrate pad group PG2 will be described by way of example, but various modifications may be made in the number of the substrate pad groups. The substrate pads 100P of the first substrate pad group PG1 may be disposed in a line parallel to the second direction D2 along the first substrate edge E1 of the package substrate 100. The substrate pads 100P of the second substrate pad group PG2 may be disposed in a line parallel in the second direction D2 along the second substrate edge E2 of the package substrate 100.

The substrate pads 100P may be bonding fingers formed to be elongated along the third direction D3. In some embodiments, pitches of the substrate pads 100P (i.e., a distance between adjacent substrate pads 100P) may each be the same, but are not limited thereto.

The bump balls B1 may be disposed on the substrate pads 100P. Each of the bump balls B1 may include a ball portion B1-1 and a neck portion B1-2. In detail, the ball portion B1-1 may be disposed to be in contact with an upper surface of one of the substrate pads 100P, and the neck portion B1-2 may be disposed on an upper surface of the ball portion B1-1. The bump balls B1 may include at least one of gold (Au), silver (Ag), copper (Cu) or aluminum (Al).

The semiconductor chip 200 may be disposed on the package substrate 100. The semiconductor chip 200 may have a plate shape including lower chip surface 200a and upper surface 200b that are opposite to each other in the first direction D1. The semiconductor chip 200 may include first through fourth chip edges E5, E6, E7, and E8, which may be lateral sides of the semiconductor chip extending from the lower surface 200a to the upper surface 200b. The first chip edge E5 and the second chip edge E6 may extend in the second direction D2 and may be spaced apart from each other in the third direction D3. The third chip edge E7 and the fourth chip edge E8 may extend in the third direction D3 and may be spaced apart from each other in the second direction D2. When the semiconductor chip 200 is disposed on the package substrate 100, the first chip edge E5 of the semiconductor chip 200 may be disposed to be closer to the first substrate edge E1 of the package substrate 100 than the second substrate edge E2 of the package substrate 100. Also, the third chip edge E7 of the semiconductor chip 200 may be disposed to be closer to the third substrate edge E3 of the package substrate 100 than the fourth substrate edge E4 of the package substrate 100.

The semiconductor chip 200 may include a first corner C5 formed at a portion where the first chip edge E5 and the third chip edge E7 intersect each other, a second corner C6 formed at a portion where the first chip edge E5 and the fourth chip edge E8 intersect each other, a third corner C7 formed at a portion where the second chip edge E6 and the fourth chip edge E8 intersect each other, and a corner C8 formed at a portion where the second chip edge E6 and the third chip edge E7 intersect each other.

In some embodiments, the semiconductor chip 200 may be a memory chip. When the semiconductor chip 200 is a memory chip, the semiconductor chip 200 may be a phase change random access memory (PRAM), a resistive random access memory (RRAM), a magnetic random access memory (MRAM), a dynamic random access memory (DRAM), or a flash memory, but is not limited thereto.

The adhesive layer 300 may be disposed between the package substrate 100 and the semiconductor chip 200. The adhesive layer 300 may be a die attach film (DAF) containing epoxy. The semiconductor chip 200 may be adhered onto the package substrate 100 by the adhesive layer 300.

The chip pads 200P and the chip dummy pads 200DP-1 to 200DP-12 may be disposed on the upper surface 200b of the semiconductor chip 200. The chip pads 200P may be disposed on the upper surface 200b of the semiconductor chip 200 and arranged ingroups. An example in which the chip pads 200P are arranged into a first chip pad group PG3 and a second chip pad group PG4 will be described by way of example, but various modifications may be made in the number of the chip pad groups. The chip pads 200P of the first chip pad group PG3 may be disposed in a line parallel to the second direction D2 along the first chip edge E5 of the semiconductor chip 200. The chip pads 200P of the second chip pad group PG4 may be disposed in a line parallel with the second direction D2 along the second chip edge E6 of the semiconductor chip 200.

Bump balls B2 may be disposed on the chip pads 200P. Each of the bump balls B2 may include a ball portion B2-1 and a neck portion B2-2. In detail, the ball portion B2-1 may be disposed to be in contact with an upper surface of a chip pad 200P, and the neck portion B2-2 may be disposed on an upper surface of the ball portion B2-1. The bump balls B2 may include at least one of gold (Au), silver (Ag), copper (Cu) or aluminum (Al).

The wires WI may electrically connect the package substrate 100 and the semiconductor chip 200 to each other. In detail, the wires W1 may connect the bump balls B1 on the substrate pad 100P of the package substrate 100 with the bump balls B2 on the chip pad 200P of the semiconductor chip 200. A first end of each wire W1 may be in contact with and connected to a respective bump ball B1 on a respective substrate pad 100P, and a second end of each wire W1 may be in contact with and connected to a respective bump ball B2 on a respective chip pad 200P.

As described above, in some embodiments, the substrate pads 100P and the wires W1 may be bonded to each other and the chip pads 200P and the wires W1 may be bonded to each other by a ball bonding method, but the embodiment is not limited thereto. For example, in another embodiment, the substrate pads 100P and the wires W1 may be bonded to each other and/or the chip pads 200P and the wire W1 may be bonded to each other by a stitch bonding method.

The semiconductor package 1000 may receive at least one of a control signal, a power signal, or a ground signal, which is required for the operation of the semiconductor chip 200, from the external device through the wires W1. In addition, the semiconductor package 1000 may receive a data signal to be stored in the semiconductor chip 200 from the external device through the wires W1 or may provide the data stored in the semiconductor chip 200 to the external device through the wires W1.

The wires W1 may be connected by any one of a thermo-compression connection, ultrasonic connection, or a thermo-sonic connection method in which thermo-compression connection and ultrasonic connection are mixed. The wires W1 may include at least one of gold (Au), silver (Ag), copper (Cu) or aluminum (Al).

The chip dummy pads 200DP-1 to 200DP-12 may be disposed on the upper surface 200b of the semiconductor chip 200 and may be arranged in groups. In some examples, a group may be a set chip dummy pads and a set of chip dummy pads may contain a single chip dummy pad. In one embodiment, the chip dummy pads 200DP-1 to 200DP-12 are arranged into a first chip dummy pad group DPG1, a second chip dummy pad group DPG2, a third chip dummy pad group DPG3, and a fourth chip dummy pad group DPG4, but the embodiment is not limited thereto. The first chip dummy pad group DPG1 may be disposed on the first corner C5 of the semiconductor chip 200, the second chip dummy pad group DPG2 may be disposed on the second corner C6 of the semiconductor chip 200, the third chip dummy pad group DPG3 may be disposed on the third corner C7 of the semiconductor chip 200, and the fourth chip dummy pad group DPG4 may be disposed on the fourth corner C8 of the semiconductor chip 200.

A plurality of chip dummy pads included in a chip dummy pad group may be disposed on at least a portion of the corners C5, C6, C7 and C8 of the semiconductor chip 200. Although FIG. 1 shows that one of the chip dummy pad groups DPG1, DPG2, DPG3 and DPG4 are disposed on a respective corner of all of the corners C5, C6, C7 and C8, the embodiment is not limited thereto. For example, the chip dummy pads may not be disposed on some of the corners C5, C6, C7 and C8 of the semiconductor chip 200.

The first chip dummy pad group DPGI may include chip dummy pads 200DP-1, 200DP-2 and 200DP-3. The chip dummy pad 200DP-1 and the chip dummy pad 200DP-2 may be disposed in a line parallel to and along the first chip edge E5. In this case, the chip dummy pad 200DP-2 may be disposed to be closer to the third chip pad group PG3 than the chip dummy pad 200DP-1. That is, a distance from the chip pad disposed at the edge in the second direction D2 among the chip pads 200P included in the third chip pad group PG3 to the chip dummy pad 200DP-2 may be shorter than a distance from the chip pad to the chip dummy pad 200DP-1.

The chip dummy pad 200DP-3 and the chip dummy pad 200DP-1 may be disposed in a line parallel to and along the third chip edge E7. In this case, the chip dummy pad 200DP-1 may be disposed to be closer to the first chip edge E5 than the chip dummy pad 200DP-3. That is, a distance from the first chip edge E5 to the chip dummy pad 200DP-1 may be shorter than a distance from the first chip edge E5 to the chip dummy pad 200DP-3. Therefore, among the chip dummy pads 200DP-1, 200DP-2, and 200DP-3 included in the first chip dummy pad group DPG1, the chip dummy pad 200DP-1 may be disposed to be closest to the first corner C5 of the semiconductor chip 200.

The second chip dummy pad group DPG2 may include chip dummy pads 200DP-4, 200DP-5 and 200DP-6. The chip dummy pad 200DP-4 and the chip dummy pad 200DP-5 may be disposed in a line parallel to and along the first chip edge E5. In this case, the fifth chip dummy pad 200DP-5 may be disposed to be closer to the third chip pad group PG3 than the chip dummy pad 200DP-4. That is, a distance from the chip pad 200P disposed at the edge in an opposite direction of the second direction D2 among the chip pads 200P included in the third chip pad group PG3 may be shorter than a distance from the chip pad to the chip dummy pad 200DP-4.

The chip dummy pad 200DP-4 and the chip dummy pad 200DP-6 may be disposed in a line parallel to and along the fourth chip edge E8. In this case, the chip dummy pad 200DP-4 may be disposed to be closer to the first chip edge E5 than the chip dummy pad 200DP-6. That is, a distance from the first chip edge E5 to the chip dummy pad 200DP-4 may be shorter than a distance from the first chip edge E5 to the chip dummy pad 200DP-6. Therefore, among the chip dummy pads 200DP-4, 200DP-5 and 200DP-6 included in the second chip dummy pad group DPG2, the chip dummy pad 200DP-4 may be disposed to be closest to the second corner C6 of the semiconductor chip 200.

The chip dummy pad group DPG3 may include chip dummy pads 200DP-7, 200DP-8 and 200DP-9. The chip dummy pad 200DP-7 and the chip dummy pad 200DP-8 may be disposed in a line parallel to and along the second chip edge E6. In this case, the chip dummy pad 200DP-8 may be disposed to be closer to the fourth chip pad group PG4 than the chip dummy pad 200DP-7. That is, a distance from the chip pad disposed at the edge in the opposite direction of the second direction D2 among the chip pads 200P included in the fourth chip pad group PG4 to the chip dummy pad 200DP-8 may be shorter than a distance from the chip pad to the chip dummy pad 200DP-7.

The chip dummy pad 200DP-7 and the chip dummy pad 200DP-9 may be disposed in a line parallel to and along the fourth chip edge E8. In this case, the chip dummy pad 200DP-7 may be disposed to be closer to the second chip edge E6 than the chip dummy pad 200DP-9. That is, a distance from the second chip edge E6 to the chip dummy pad 200DP-7 may be closer than a distance from the second chip edge E6 to the chip dummy pad 200DP-9. Therefore, among the chip dummy pads 200DP-7, 200DP-8 and 200DP-9 included in the third chip dummy pad group DPG3, the chip dummy pad 200DP-7 may be disposed to be closest to the third corner C7 of the semiconductor chip 200.

The fourth chip dummy pad group DPG4 may include chip dummy pads 200DP-10, 200DP-11 and 200DP-12. The chip dummy pad 200DP-10 and the chip dummy pad 200DP-11 may be disposed in a line parallel to and along the second chip edge E6. In this case, the chip dummy pad 200DP-11 may be disposed to be closer to the fourth chip pad group PG4 than the chip dummy pad 200DP-10. That is, a distance from the chip pad disposed at the edge in the second direction D2 among the chip pads 200P included in the fourth chip pad group PG4 to the chip dummy pad 200DP-11 may be shorter than a distance from the chip pad to the chip dummy pad 200DP-10.

The chip dummy pad 200DP-10 and the chip dummy pad 200DP-12 may be disposed in a line parallel to and along the third chip edge E7. In this case, the chip dummy pad 200DP-10 may be disposed to be closer to the second chip edge E6 than the chip dummy pad 200DP-12. That is, a distance from the second chip edge E6 to the chip dummy pad 200DP-10 may be closer than a distance from the second chip edge E6 to the chip dummy pad 200DP-12. Therefore, among the chip dummy pads 200DP-10, 200DP-11 and 200DP-12 included in the fourth chip dummy pad group DPG4, the chip dummy pad 200DP-10 may be disposed to be closest to the fourth corner C8 of the semiconductor chip 200.

In the following description, the first chip dummy pad group DPG1 disposed on the first corner C5 will be described, and since the other chip dummy pad groups DPG2, DPG3 and DPG4 are similar to the chip dummy pad group DPG1, their detailed description would be redundant and will be omitted with the understanding that the description of the first chip dummy pad group DPG1 is applicable to the other chip dummy pad groups DPG2, DPG3 and DPG4.

Unlike the chip pads 200P used to electrically connect the semiconductor chip 200 with the package substrate 100, the chip dummy pads 200DP-1, 200DP-2 and 200DP-3 may be dummy components that are not used to electrically connect the semiconductor chip 200 to any external device. The chip dummy pads described herein (e.g., chip dummy pads 200DP-1, 200DP-2 and 200DP-3) may not have any electrical connection to any of the integrated circuits of the semiconductor chip 200. However, the chip dummy pads may have the same or similar structure and/or shape as the normal chip pads (e.g., 200P) of semiconductor chip 200, including being formed of the same material (e.g., formed of the same material layer at the same the level). For example, upper surfaces of the chip dummy pads and the normal chip pads of the semiconductor chip may be coplanar. The chip dummy pads may not be used to convey signals or power (unlike normal chip pads which are connected to internal circuitry of the semiconductor chip to communicate signals and/or power). In some instances, the chip dummy pads may form all or part of an electrical node that is electrically floated (e.g., not electrically (directly or indirectly) connected to any other conductor). The chip dummy pads (along with the normal chip pads) may be elements of the uppermost conductive layer (c.g., metal layer) of the chip 200. In some examples, the chip dummy pads and the normal chip pads may be covered by a passivation layer that is then patterned to expose the chip dummy pads and the normal chip pads.

The chip dummy pads 200DP-1, 200DP-2 and 200DP-3 may be used to press the first corner C5 of the semiconductor chip 200 in the opposite direction of the first direction D1 (e.g., a downward direction) by applying pressure to the first corner C5 of the semiconductor chip 200. For example, a chip dummy pad that is larger relative to the chip pads may allow for a relatively larger bump ball, which may result in additional force being applied at the location of the chip dummy pad during fabrication of the semiconductor package. For example, a larger chip dummy pad and bump ball at a corner of a semiconductor chip may result in an increased downward force at the corner during fabrication of the semiconductor package. The chip dummy pads 200DP-1, 200DP-2, and 200DP-3 may be disposed on the first corner C5 of the semiconductor chip 200 and may be formed to apply downward pressure to the first corner C5 of the semiconductor chip 200, thereby preventing the first corner C5 of the semiconductor chip 200 from being delaminated from the package substrate 100 when the semiconductor chip 200 is packaged on the package substrate 100. Therefore, when the semiconductor chip 200 is bonded onto the package substrate 100 by a wire bonding method, delamination of the first corner C5 of the semiconductor chip 200 from an upper surface of the package substrate 100 in the first direction DI may be alleviated.

In some embodiments, a size of each of the chip dummy pads 200DP-1, 200DP-2, and 200DP-3 may be larger than that of the chip pad 200P. For example, a length of a chip pad 200P in the second direction D2 and a length of a chip pad 200P in the third direction D3 may be 80um, and a length of each of the chip dummy pads 200DP-1, 200DP-2 and 200DP-3 in the second direction D2 and a length of each of them in the third direction D3 may be 150 μm, respectively. The chip dummy pads 200DP-1, 200DP-2 and 200DP-3 may include at least one of copper (Cu), aluminum (Al), silver (Ag), tin (Sn), gold (Au), nickel (Ni), lead (Pb), titanium (Ti) or their alloy, but are not limited thereto.

The A bump ball B3 may be disposed on the chip dummy pad 200DP-1. The bump ball B3 may include a ball portion B3-1 and a neck portion B3-2. In detail, the ball portion B3-1 may be disposed to be in contact with an upper surface of the chip dummy pad 200DP-1, and the neck portion B3-2 may be disposed on an upper surface of the ball portion B3-1. The bump ball B3 may include at least one of gold (Au), silver (Ag), copper (Cu) or aluminum (Al).

The size of the bump ball B3 on the chip dummy pad 200DP-1 may be larger than that of the bump balls B2 on the chip pads 200P. For example, lengths of the bump ball B3 in the first to third directions D1, D2, and D3 may be larger than those of the bump balls B2 in the first to third directions D1, D2, and D3. Since the size of the chip dummy pad 200DP-1 is implemented to be larger than that of the chip pads 200P, the size of the bump ball B3 disposed on the chip dummy pad 200DP-1 may be also implemented to be larger than that of the bump balls B2 disposed on the chip pads 200P.

Bump balls B4, B5, B6, B7, B8, B9, B10, B11, B12, B13, and B14 may be respectively disposed on the chip dummy pads 200DP-2, 200DP-3, 200DP-4, 200DP-5, 200DP-6, 200DP-7, 200DP-8, 200DP-9, 200DP-10, 200DP-11 and 200DP-12. The description of the bump balls B4, B5, B6, B7, B8, B9, B10, B11, B12, B13 and B14 is the same as that of the bump ball B3 and thus will be omitted with the understanding that the description of bump ball B3 is applicable to the balls B4, B5, B6, B7, B8, B9, B10, B11, B12, B13 and B14.

Hereinafter, other embodiments will be described, and the description of clements described previously with respect to FIGS. 1 though 4 may be omitted, and the following description will be based on differences from the aforementioned embodiments.

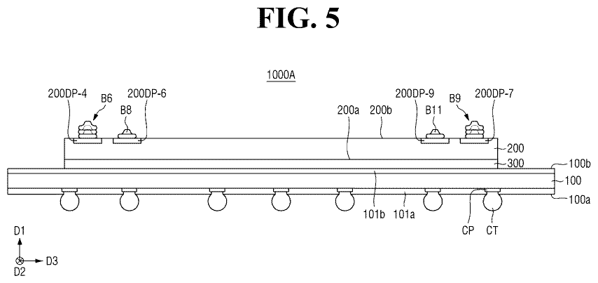

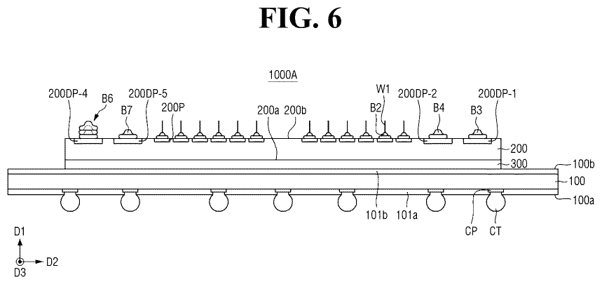

FIGS. 5 and 6 are example views illustrating a semiconductor package according to some other embodiments. FIG. 5 is a view corresponding to FIG. 3, and FIG. 6 is a view corresponding to FIG. 4. Hereinafter, the second chip dummy pad group DPG2 will be described as an example, but the same description may be also applied to the other chip dummy pad groups DPG1, DPG3 and DPG4.

Referring to FIGS. 5 and 6, unlike the embodiment described with reference to FIGS. 1 to 4, the number of bump balls B6 disposed on the chip dummy pad 200DP-4 of the semiconductor package 1000A may be greater than the number of bump balls B8 disposed on the chip dummy pad 200DP-6 and the number of bump balls B7 disposed on the chip dummy pad 200DP-5. For example, as shown in FIGS. 5 and 6, three bump balls B6 may be disposed on the chip dummy pad 200DP-4 to overlap one another in the first direction D1, whereas one bump ball B8 may be disposed on the chip dummy pad 200DP-6. However, the number of bump balls B6, B7 and B8 disposed on the chip dummy pads 200DP-4, 200DP-5 and 200DP- 6 is not limited to those shown in FIGS. 5 and 6.

As described above, the number of bump balls B6 disposed on the fourth chip dummy pad 200DP-4 disposed to be closest to the second corner C6 of the semiconductor chip 200 among the chip dummy pads 200DP-4, 200DP-5 and 200DP-6 included in the second chip dummy pad group DPG2 disposed on the second corner C6 may be greater than the number of bump balls B7 and B8 disposed on the other chip dummy pads 200DP-5 and 200DP-6, respectively. In this way, more bump balls may be disposed on a chip dummy pad disposed at a position closest to the corner of the semiconductor chip 200, which is a position where delamination of the semiconductor chip 200 occurs most frequently, whereby delamination of the semiconductor chip 200 may be efficiently alleviated.

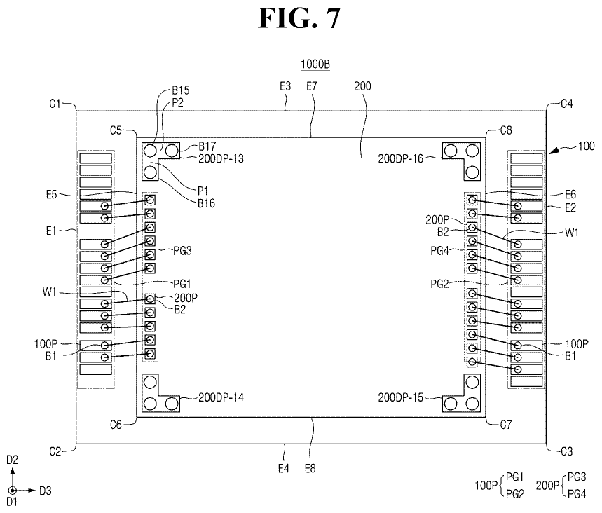

FIG. 7 is an example view illustrating a semiconductor package according to some other embodiments.

Referring to FIG. 7, the chip dummy pads 200DP-13, 200DP-14, 200DP-15 and 200DP-16 may be disposed on the upper surface 200b of the semiconductor chip 200 in the semiconductor package 1000B. The chip dummy pads 200DP-13, 200DP-14, 200DP-15 and 200DP-16 may be disposed on the corners C5, C6, C7 and C8 of the semiconductor chip 200, respectively. Since the description of the chip dummy pads 200DP-14, 200DP-15 and 200DP-16 is the same as the description of the chip dummy pad 200DP-13, the description of the other chip dummy pads 200DP-14, 200DP-15 and 200DP-16 may be omitted with the understanding that the description of the chip dummy pad 200DP-13 is applicable.

The chip dummy pad 200DP-13 may include a first portion PI and a second portion P2. The first portion PI of the chip dummy pad 200DP-13 may extend along the first chip edge E5 of the semiconductor chip 200, and the second portion P2 of the chip dummy pad 200DP-13 may extend along the third chip edge E7 of the semiconductor chip 200. One end of the first portion P1 and one end of the second portion P2 may be joined to each other on the first corner C5 of the semiconductor chip 200.

A plurality of bump balls B15, B16 and B17 may be disposed on the chip dummy pad 200DP-13. Since the bump balls B15, B16 and B17 are similar to the bump balls in the above-described embodiments, their description will be omitted with the understanding that the preceding description is applicable. The bump ball B15 and the bump ball B16 may be disposed in a linc parallel with and along the first chip edge E5, and the bump ball B15 and the bump ball B17 may be disposed in a line parallel with and along the third chip edge E7. The bump ball B15 may be disposed to be closest to the first corner C5 than the other bump balls B16 and B17. In some embodiments, the number of bump balls B15 disposed to be closest to the first corner C5 may be greater than the number of the other bump balls B16 and B17.

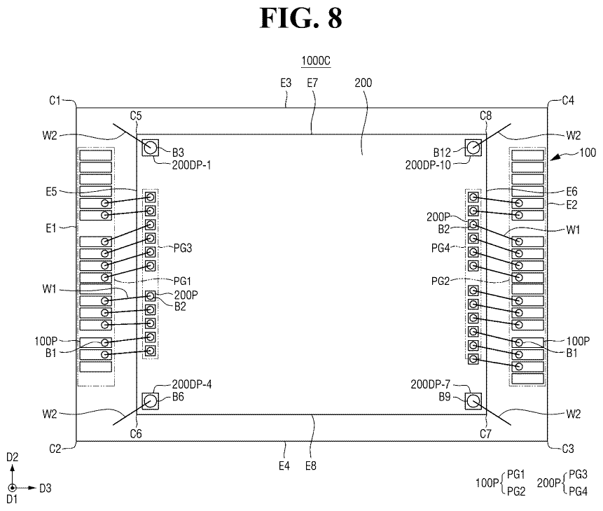

Hereinafter, in FIGS. 8 to 13, the description will be based on the configuration of one second corner C6 among the corners C5, C6, C7 and C8 of the semiconductor chip 200. However, the following description may be equally applied to the configuration of the other corners C5, C7 and C8.

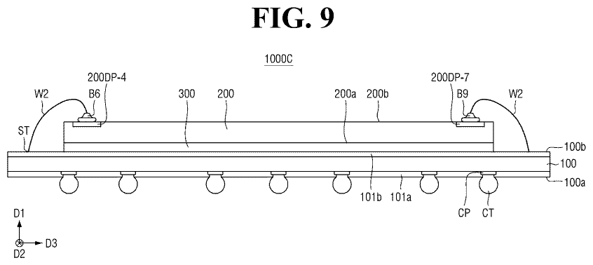

FIGS. 8 and 9 are example views illustrating a semiconductor package according to some other embodiments.

Referring to FIGS. 8 and 9, a semiconductor package 1000C may further include a wire W2. Since the wire W2 is similar to the wire W1, its redundant description will be omitted with the understanding the description of the wire W1 is generally applicable to wire W2. The following description will be based on differences from the wire W1. A first end of the wire W2 may be connected to the bump ball B6, and a second end of the wire W2 may be connected to the upper surface 200b of the package substrate 100. The first end of the wire W2 and the chip dummy pad 200DP-4 may be bonded to each other by a ball bonding method, and the second end of the wire W2 and the upper surface 200b of the package substrate 100 may be bonded to each other by a stitch bonding method, but the embodiment is not limited thereto. In embodiments in which the second end of the wire W2 and the upper surface 200b of the package substrate 100 are bonded to each other by a stitch bonding method, a stitch portion ST of the wire W2 may be disposed to be in contact with the upper surface 200b of the package substrate 100.

Unlike the wire W1, the wire W2 may be a dummy wire. That is, the wire W1 is a component that electrically connects the semiconductor chip 200 with the package substrate 100, whereas the wire W2 may be a dummy component that is not used to electrically connect the semiconductor chip 200 with the external device including the package substrate 100. The wire W2 is formed between the bump ball B6 and the package substrate 100, and thus may serve to support the chip dummy pad 200DP-4 and the bump ball B6 so that they apply more stable pressure to the second corner C6 of the semiconductor chip 200 when applying the pressure to the second corner C6 of the semiconductor chip 200 to prevent delamination of the semiconductor chip 200 from occurring.

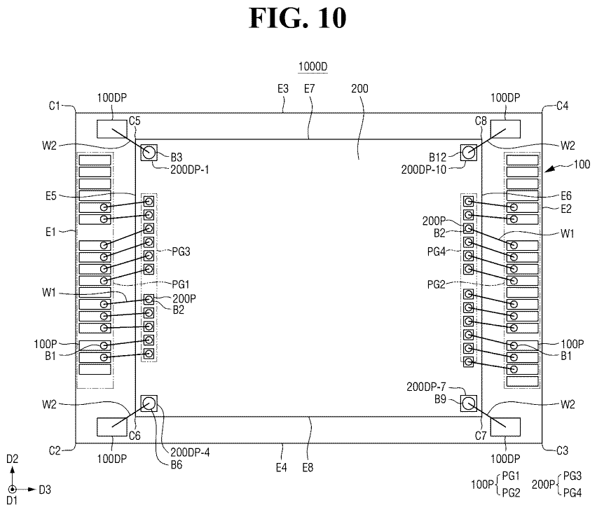

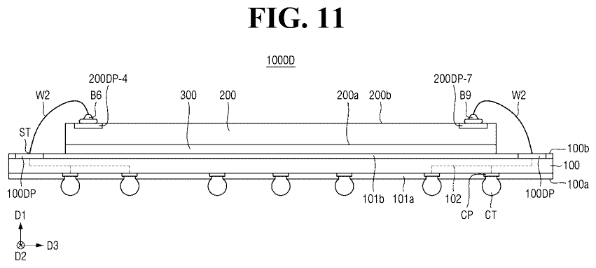

FIGS. 10 and 11 are example views illustrating a semiconductor package according to some other embodiments.

Referring to FIGS. 10 and 11, a semiconductor package 1000D may further include a substrate dummy pad 100DP. Since the substrate dummy pad 100DP is similar to the chip dummy pad 200DP-4, its redundant description will be omitted with the understanding that the description of chip dummy pad 200DP-4 is applicable to substrate dummy pad 100DP, and the following description will be based on differences from the chip dummy pad 200DP-4. The substrate dummy pad 100DP may be disposed on the upper surface 100b of the package substrate 100. The substrate dummy pad 100DP may be disposed as a plurality of substrate dummy pads 100DP to correspond to the chip dummy pads 200DP-1, 200DP-4, 200DP-7 and 200DP-10 on the semiconductor chip 200. The other end of the wire W2 may be connected to the substrate dummy pad 100DP. The wire W2 and the substrate dummy pad 100DP may be bonded to each other by a stitch bonding method. The stitch portion ST of the wire W2 may be disposed to be in direct contact with an upper surface of the substrate dummy pad 100DP. As described above, when the other end of the wire W2 is bonded to the substrate dummy pad 100DP formed on the upper surface 100b of the package substrate 100, the wire W2 may be more structurally stable.

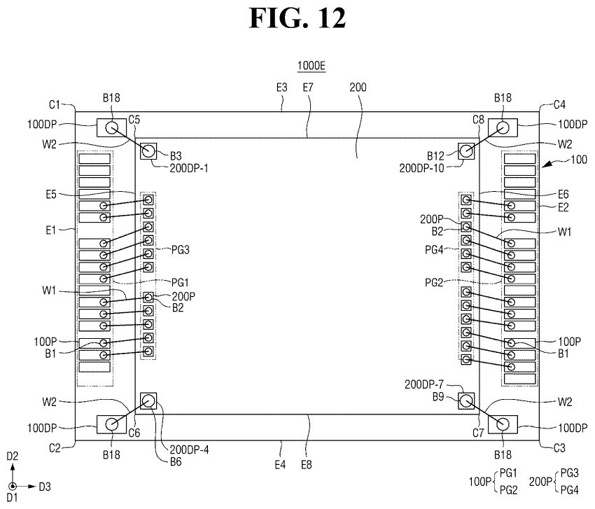

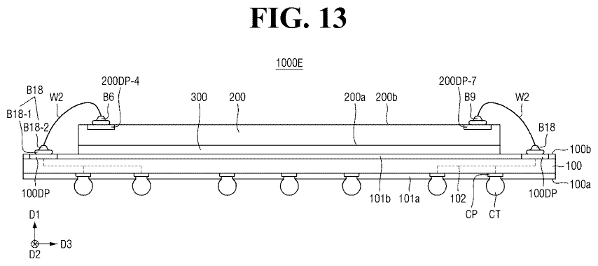

FIGS. 12 and 13 are example views illustrating a semiconductor package according to some other embodiments.

Referring to FIGS. 12 and 13, the semiconductor package 1000E may further include another bump ball B18. Since the bump ball B18 is similar to the bump ball B6, its description may be redundant and therefore portions may be omitted with the understanding that the description of bump ball B6 is applicable to bump ball B18, and the following description will be based on differences from the bump ball B6. The bump ball B18 may be disposed on the substrate dummy pad 100DP. The bump ball B18 may include a ball portion B18-1 and a neck portion B18-2. In detail, the ball portion B18-1 may be disposed to be in contact with the upper surface of the substrate dummy pad 100DP, and the neck portion B18-2 may be disposed on an upper surface of the ball portion B18-1. The other end of the wire W2 may be connected to the bump ball B18. That is, the wire W2 may be connected to the substrate dummy pad 100DP through the bump ball B18. The wire W2 and the substrate dummy pad 100DP may be bonded to each other by a ball bonding method. The other end of the wire W2 may be disposed to be directly in contact with an upper end of the bump ball B18.

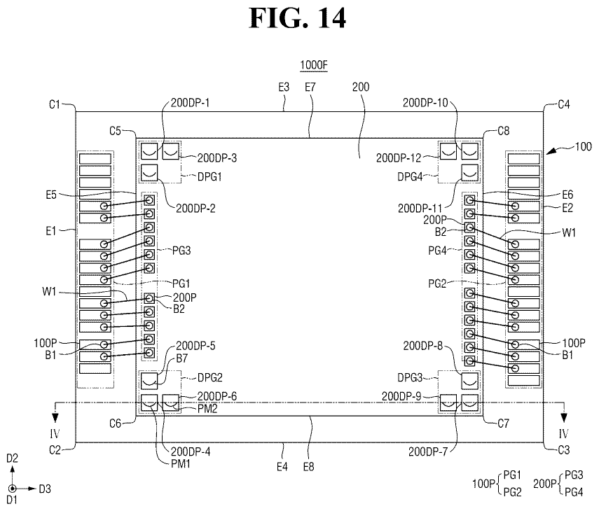

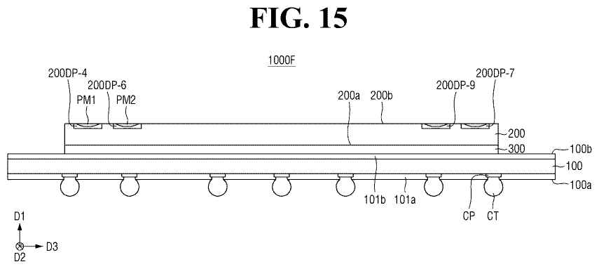

FIGS. 14 and 15 are example views illustrating a semiconductor package according to some other embodiments. FIG. 15 is a cross-sectional view taken along line IV- IV of FIG. 14.

Referring to FIGS. 14 and 15, unlike the embodiment described with reference to FIG. 1, bump balls may not be disposed on the upper surface of each of the chip dummy pads included in the dummy pad groups DPG1, DPG2, DPG3 and DPG4 of a semiconductor package 1000F. Instead, a capillary mark may be formed on the upper surface of each of the chip dummy pads. Hereinafter, the chip dummy pads 200DP-4 and 200DP-6 included in the second chip dummy pad group DPG2 will be described, but the description is applicable to the other chip dummy pads disposed on the upper surface 200b of the semiconductor chip 200.

A first capillary mark PMI may be formed in the chip dummy pad 200DP-4 at an upper surface of the chip dummy pad 200DP-4. Likewise, a second capillary mark PM2 may be formed in the chip dummy pad 200DP-6 at an upper surface of the chip dummy pad 200DP-6.

Conventionally, after a die attach process of bonding a semiconductor chip onto a package substrate is performed, the corners of the semiconductor chip may be delaminated from the package substrate. In order to alleviate delamination of the semiconductor chip 200 from the package substrate 100, the chip dummy pads 200DP-4, 200DP-5 and 200DP-6 may be formed on a corner portion (e.g., the second corner C6) of the upper surface 200b of the semiconductor chip 200. In this case, the upper surfaces of the chip dummy pads 200DP-4, 200DP-5 and 200DP-6 may be pressed using a capillary, which is a type of a wire bonding device, to alleviate delamination of the second corner C6 of the semiconductor chip 200 from the package substrate 100. The capillary marks PMI and PM2 may be formed in the process of adhering the second corner C6 of the semiconductor chip 200 to the package substrate 100 by applying pressure to the upper surfaces of the chip dummy pads 200DP-4 and 200DP-6 by using a capillary.

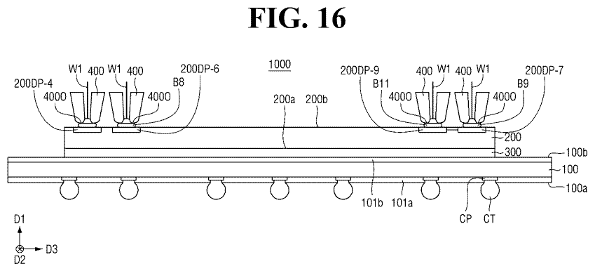

Hereinafter, in FIGS. 16 to 20, the description will be based on the chip dummy pad 200DP-4 among the chip dummy pads of the upper surface 200b of the semiconductor chip 200, but the following description may be equally applied to other chip dummy pads of the upper surface 200b of the semiconductor chip 200.

FIG. 16 is an example view illustrating a method of fabricating the semiconductor package of FIGS. 1 to 4.

Referring to FIG. 16, a wire W for forming bump balls B6 may be mounted on a capillary 400. The capillary 400 may support the wire W and may be provided with a front end opening 4000 therebelow, which discharges the wire W therefrom. The capillary 400 may come in contact with the chip dummy pad 200DP-4 by descending toward the upper surface of the chip dummy pad 200DP-4 while supporting the wire W. In this case, an electric spark or the like may be provided to the wire W protruded from a center hole of the capillary 400 so that a lower end of the wire W may be melted. Therefore, in the center hole of the capillary 400, the bump ball B6 may be formed on the lower end of the wire W. As shown in FIG. 3, when only the bump ball B6 is formed on the chip dummy pad 200DP-4 and the semiconductor chip 200 and the package substrate 100 are not connected to each other using the wire W, the capillary 400 may disconnect the wire W after the bump ball B6 is formed.

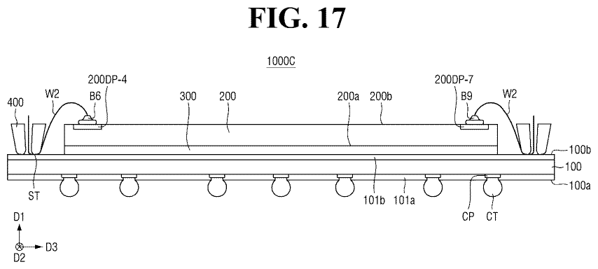

FIG. 17 is an example view illustrating a method of fabricating the semiconductor package of FIGS. 8 and 9.

Referring to FIG. 17, the capillary 400 may move onto the upper surface 100b of the package substrate 100 to guide the wire W2 after the bump ball B6 is formed on the chip dummy pad 200DP-4. That is, the capillary 400, which has moved upward in the first direction D1 from the chip dummy pad 200DP-4, may slide toward the upper surface 100b of the package substrate 100. In this case, the wire W2 discharged from a lower end of the capillary 400 may be extended in accordance with the sliding of the capillary 400. As a result, the wire W2 may be formed between the bump ball B6 and the upper surface 100b of the package substrate 100. The capillary 400 moved onto the upper surface 100b of the package substrate 100 may bond the wire W2 to the upper surface 100b of the package substrate 100. Afterwards, the capillary 400 may move upward in the first direction D1 from the upper surface 100b of the package substrate 100, and thus the wire W2 may be completely disconnected from the stitch portion ST.

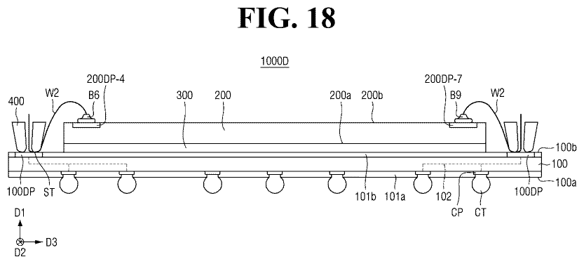

FIG. 18 is an example view illustrating a method of fabricating the semiconductor package of FIGS. 10 and 11.

Referring to FIG. 18, unlike FIG. 17, the bump ball B6 is formed on the chip dummy pad 200DP-4 and the capillary 400 moved upward in the first direction D1 from the chip dummy pad 200DP-4 may slide toward the substrate dummy pad 100DP. As a result, the wire W2 may be formed between the bump ball B6 and the substrate dummy pad 100DP. The capillary 400, which have moved onto the upper surface of the substrate dummy pad 100DP, may bond the wire W2 to the upper surface of the substrate dummy pad 100DP. Afterwards, the capillary 400 may move upward in the first direction D1 from the upper surface of the substrate dummy pad 100DP, and thus the wire W2 may be completely disconnected from the stitch portion ST. Therefore, the stitch portion ST of the wire W2 may be directly in contact with the upper surface of the substrate dummy pad 100DP.

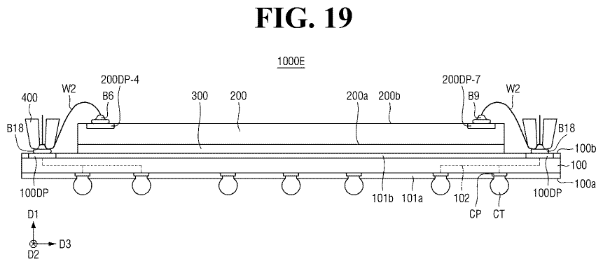

FIG. 19 is an example view illustrating a method of fabricating the semiconductor package of FIGS. 12 and 13.

Referring to FIG. 19, unlike FIG. 18, in a state that the capillary 400 supports the wire W2 and descends to the upper surface of the substrate dummy pad 100DP to contact the substrate dummy pad 100DP, an electric spark or the like may be provided to the wire W2 protruded from the center hole of the capillary 400 so that a lower end of the wire W2 may be melted. Therefore, in the center hole of the capillary 400, the bump ball B18 may be formed on the lower end of the wire W2. Afterwards, the capillary 400 may move upward in the first direction D1 from the upper surface of the substrate dummy pad 100DP, and thus the wire W2 may be completely disconnected from the bump ball B18.

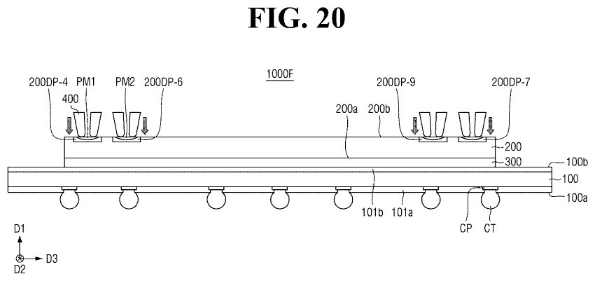

FIG. 20 is an example view illustrating a method of fabricating the semiconductor package of FIGS. 14 and 15.

Referring to FIG. 20, the capillary 400 may move in the opposite direction of the first direction D1 to press the upper surface of the chip dummy pad 200DP-4. In this process, the capillary mark PM1 may be formed on the upper surface of the chip dummy pad 200DP-4. Likewise, the capillary 400 may move in the opposite direction of the first direction D1 to press the upper surface of the chip dummy pad 200DP-6, and thus the capillary mark PM2 may be formed on the upper surface of the chip dummy pad 200DP-6.

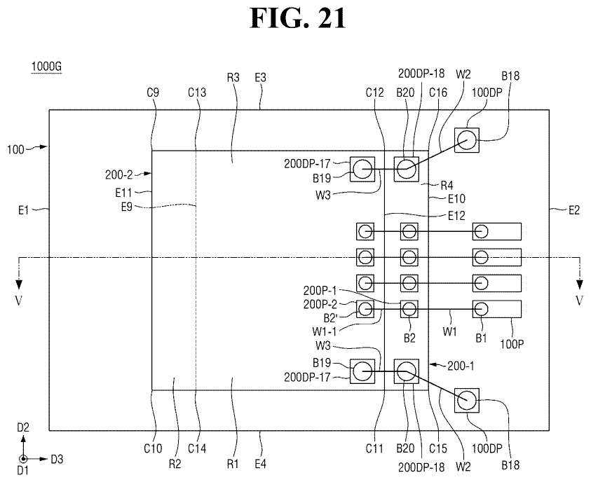

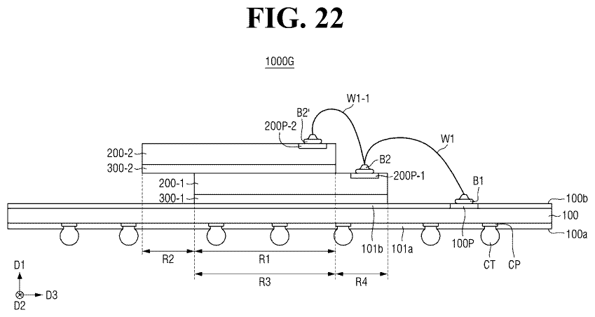

FIGS. 21 and 22 are example views illustrating a semiconductor package according to some other embodiments. FIG. 22 is a cross-sectional view taken along line V-V of FIG. 21.

Referring to FIGS. 21 and 22, a semiconductor package 1000G may include a package substrate 100, a semiconductor chip 200-1, and a semiconductor chip 200-2. Since the semiconductor chips 200-1 and 200-2 are similar to the semiconductor chip 200 according to the above-described embodiments, their redundant description may be omitted, and the following description will be based on differences from the above-described embodiments with the understanding that the description of semiconductor chip 200 is applicable to semiconductor chips 200-1 and 200-2.

The first semiconductor chip 200-1 may be disposed on the package substrate 100, and the second semiconductor chip 200-2 may be disposed on the first semiconductor chip 200-1. An adhesive layer 300-1 may be disposed between the package substrate 100 and the first semiconductor chip 200-1, and an adhesive layer 300-2 may be disposed between the first semiconductor chip 200-1 and the second semiconductor chip 200-2. Each of the first semiconductor chip 200-1 and the second semiconductor chip 200-2 on the package substrate 100 may form a cascade structure in which they are stacked in a stepwise shape. The upper surface of the second semiconductor chip 200-2 may include a first region R1 and a second region R2, which do not overlap each other. The first region R1 may vertically overlap the first semiconductor chip 200-1, and the second region R2 may not vertically overlap the first semiconductor chip 200-1.

The second semiconductor chip 200-2 may include an overhang region that extends beyond a side of the first semiconductor chip 200-1 disposed therebelow. That is, the overhang region of the second semiconductor chip 200-2 disposed thereon may be defined as a region extending in an opposite direction of the third direction D3 without being supported by the first semiconductor chip 200-1 disposed therebelow. The second region R2 of the second semiconductor chip 200-2 may correspond to the overhang region.

The upper surface of the first semiconductor chip 200-1 may include a third region R3 and a fourth region R4, which do not overlap each other. The third region R3 may vertically overlap the adhesive layer 300-2, and the fourth region R4 may not vertically overlap the adhesive layer 300-2. That is, the fourth region R4 of the upper surface of the semiconductor chip 200-1 may not be covered by the adhesive layer 300-2.

The package substrate 100 may include substrate pads 100P. The substrate pads 100P may be disposed along the second substrate edge E2 of the package substrate 100. The bump balls B1 may be disposed on the substrate pads 100P, respectively.

The first semiconductor chip 200-1 may include a first chip edge E9 and a second chip edge E10, which extend in the second direction D2, respectively. The first chip edge E9 and the second chip edge E10 may be spaced apart from each other in the third direction D3. The second chip edge E10 of the first semiconductor chip 200-1 may be disposed to be closer to the second substrate edge E2 of the package substrate 100 than the first substrate edge E1 of the package substrate 100. Chip pads 200P-1 may be disposed along the second chip edge E10 of the semiconductor chip 200-1. The bump balls B2 may be disposed on the chip pads 200P-1, respectively. The bump balls B1 and the bump balls B2 may be connected to each other through the wires W1, respectively.

The semiconductor chip 200-2 may include a first chip edge E11 and a second chip edge E12, which extend in the second direction D2, respectively. The first chip edge E11 and the second chip edge E12 may be spaced apart from each other in the third direction D3. The second chip edge E12 of the second semiconductor chip 200-2 may be included in the first region R1. The first chip edge Ell of the second semiconductor chip 200-2 may be included in the second region R2. The second chip edge E12 of the second semiconductor chip 200-2 may be disposed to be closer to the second chip edge E10 of the first semiconductor chip 200-1 than the first chip edge E9 of the first semiconductor chip 200-1.

Chip pads 200P-2 may be disposed along the second chip edge E12 of the second semiconductor chip 200-2. Bump balls B2′ may be disposed on the chip pads 200P-2, respectively. The bump balls B2 and the bump balls B2′ may be connected to each other through wires W1-1, respectively.

The second semiconductor chip 200-2 may include corners C9, C10, C11 and C12. The corners C11 and C12 may be included in the first region R1, and the corners C9 and C10 may be included in the second region R2. Chip dummy pads 200DP-17 and bump balls B19 may be disposed on the corners C11 and C12 included in the first region R1, respectively.

The semiconductor chip 200-1 may include corners C13, C14, C15 and C16. The corner C16 of the semiconductor chip 200-1 may be disposed to be adjacent to the corner C12 of the semiconductor chip 200-2, and the corner C15 of the semiconductor chip 200-1 may be disposed to be adjacent to the corner C11 of the semiconductor chip 200-2. Chip dummy pads 200DP-18 and bump balls B20 may be disposed on the corners C15 and C16, respectively. Wires W3 may connect the bump balls B19 to the bump balls B20, respectively.

As described above, each of the semiconductor chip 200-1 and the semiconductor chip 200-2, which are stacked on the package substrate 100 in a cascade structure, may include a chip dummy pad and a bump ball at corner portions thereof. Also, the bump ball of the semiconductor chip 200-1 and the bump ball of the semiconductor chip 200-2 may be connected to each other through wires. Therefore, when the semiconductor chip 200-2 is stacked on the semiconductor chip 200-1, delamination of the corner portion of the semiconductor chip 200-2 from the semiconductor chip 200-1 may be alleviated.

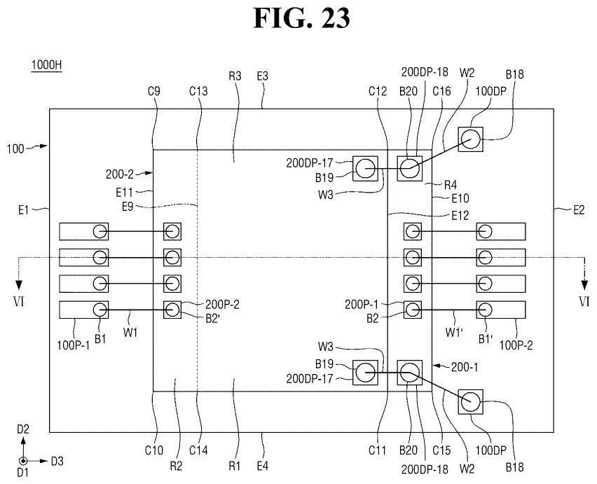

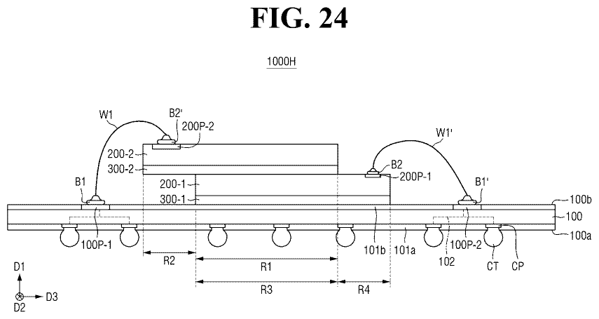

FIGS. 23 and 24 are example views illustrating a semiconductor package according to some other embodiments. FIG. 24 is a cross-sectional view taken along VI-VI of FIG. 23.

Referring to FIGS. 23 and 24, unlike the embodiment described with reference to FIGS. 21 and 22, substrate pads of the package substrate 100 in a semiconductor package 1000H may be divided into substrate pads 100P-1 disposed along the first substrate edge E1 of the package substrate 100 and substrate pads 100P-2 disposed along the second substrate edge E2 of the package substrate 100. Also, the chip pads 200P-2 of the semiconductor chip 200-2 may be disposed along the edge E11 included in the second region R2. That is, the chip pads 200P-2 may be disposed in the second region R2 of the semiconductor chip 200-2 corresponding to the overhang region.

Bump balls B1′ may be disposed on the substrate pads 100P-2 disposed along the second substrate edge E2 of the package substrate 100. Bump balls B2 may be disposed on the chip pads 200P-1 disposed along the edge E10 of the semiconductor chip 200-1. The bump balls B1′ and the bump balls B2 may be connected to each other through wires W1′, respectively.

Meanwhile, as shown in FIGS. 23 and 24, when chip pads 200P-2 and bump balls B2′ are disposed in the overhang region of the semiconductor chip 200-2 and the bump balls B2′ are respectively connected to the substrate pads 100P-1 of the package substrate 100 through the wires W1, a possibility that the corners C11 and C12 included in the first region R1 of the semiconductor chip 200-2 are delaminated from the semiconductor chip 200-1 may be increased. Therefore, the chip dummy pads 200DP-17 and the bump balls B19 are disposed at each of the corners C11 and C12 of the semiconductor chip 200-2, so that delamination of the corners C11 and C12 of the semiconductor chip 200-2 from the semiconductor chip 200-1 may be alleviated.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor package comprising:
a package substrate including first and second surfaces opposite to each other in a first direction, a plurality of substrate pads on the second surface, and first and second substrate edges respectively extending in a second direction intersecting the first direction and spaced apart from each other in a third direction intersecting the first and second directions;
a first semiconductor chip on the package substrate, including third and fourth surfaces opposite to each other in the first direction, a plurality of chip pads and a plurality of chip dummy pad groups on the fourth surface, and first and second chip edges respectively extending in the second direction and spaced apart from each other in the third direction; and
a plurality of first wires, each first wire of the plurality of first wires respectively connecting a respective substrate pad of the plurality of substrate pads with a respective chip pad of the plurality of chip pads,
wherein the first chip edge is closer to the first substrate edge than the second substrate edge,
each substrate pad of the plurality of substrate pads is disposed along the first substrate edge,
each chip pad of the plurality of chip pads is disposed along the first chip edge,
the first semiconductor chip includes third and fourth chip edges respectively extending in the third direction and spaced apart from each other in the second direction, a first corner formed at the intersection of the first chip edge and the third chip edge, a second corner formed at the intersection of the first chip edge and the fourth chip edge, a third corner formed at the intersection of the second chip edge and the fourth chip edge, and a fourth corner formed at the intersection of the second chip edge and the third chip edge, and
each chip dummy pad group of the plurality of chip dummy pad groups is respectively disposed at one of the first to fourth corners.

2. The semiconductor package of claim 1, wherein the plurality of chip dummy pad groups includes a first chip dummy pad group including a first chip dummy pad, a second chip dummy pad, and a third chip dummy pad, and
the first chip dummy pad, the second chip dummy pad, and the third chip dummy pad are disposed at the first corner.

3. The semiconductor package of claim 2, wherein the first chip dummy pad and the second chip dummy pad are disposed in a line parallel with the first chip edge, and
a distance from the plurality of chip pads to the second chip dummy pad is shorter than a distance from the plurality of chip pads to the first chip dummy pad.

4. The semiconductor package of claim 3, further comprising at least one first bump ball on the first chip dummy pad and at least one second bump ball on the second chip dummy pad.

5. The semiconductor package of claim 4, wherein the number of the first bump balls on the first chip dummy pad is greater than the number of the second bump balls on the second chip dummy pad.

6. The semiconductor package of claim 4, further comprising a second wire,
wherein a first end of the second wire is connected to the first bump ball, and a second end of the second wire is connected to the second surface of the package substrate.

7. The semiconductor package of claim 4, further comprising:
a second wire; and
a substrate dummy pad on the second surface of the package substrate,
wherein a first end of the second wire is connected to the first bump ball, and a second end of the second wire is connected to the substrate dummy pad.

8. The semiconductor package of claim 7, further comprising a third bump ball on the substrate dummy pad,
wherein the second end of the second wire is connected to the substrate dummy pad through the third bump ball.

9. The semiconductor package of claim 3, wherein the first chip dummy pad and the third chip dummy pad are disposed in a line parallel with the third chip edge, and
a distance from the first chip edge to the first chip dummy pad is shorter than a distance from the first chip edge to the third chip dummy pad.

10. The semiconductor package of claim 9, further comprising at least two first bump balls on the first chip dummy pad and at least one second bump ball on the third chip dummy pad,
wherein the number of the first bump balls on the first chip dummy pad is greater than the number of the second bump balls on the third chip dummy pad.

11. A semiconductor package comprising:
a first semiconductor chip including first and second surfaces opposite to each other in a first direction, a plurality of first chip pads on the second surface, and first and second chip edges respectively extending in a second direction intersecting the first direction and spaced apart from each other in a third direction intersecting the first and second directions;
a second semiconductor chip disposed on the first semiconductor chip, including third and fourth surfaces opposite to each other in the first direction, a plurality of second chip pads and a plurality of chip dummy pads on the fourth surface, and third and fourth chip edges respectively extending in the second direction and spaced apart from each other in the third direction; and
a plurality of first wires, each first wire of the plurality of first wires respectively connecting a respective first chip pad of the plurality of first chip pads with a respective second chip pad of the plurality of second chip pads,
wherein the third chip edge is closer to the first chip edge than the second chip edge,
each first chip pad of the plurality of first chip pads is disposed along the first chip edge,
each second chip pad of the plurality of second chip pads is disposed along the third chip edge,
the second semiconductor chip includes fifth and sixth chip edges respectively extending in the third direction and spaced apart from each other in the second direction, a first corner formed at the intersection of the third chip edge and the fifth chip edge, and a second corner formed at the intersection of the third chip edge and the sixth chip edge, and
each chip dummy pad of the plurality of chip dummy pads is disposed at one of the first corner or the second corner.

12. The semiconductor package of claim 11, wherein the plurality of chip dummy pads includes a first chip dummy pad, a second chip dummy pad, and a third chip dummy pad,
the first chip dummy pad, the second chip dummy pad, and the third chip dummy pad are disposed at the first corner,
the first chip dummy pad and the second chip dummy pad are disposed in a line parallel to the third chip edge, and
the third chip dummy pad and the first chip dummy pad are disposed in a line parallel to the fifth chip edge.

13. The semiconductor package of claim 11, wherein the plurality of chip dummy pads includes a first chip dummy pad disposed at the first corner and a second chip dummy pad disposed at the second corner,
the semiconductor package further comprising at least one first bump ball on the first chip dummy pad and at least one second bump ball on the second chip dummy pad.

14. The semiconductor package of claim 13, further comprising an adhesive layer between the first semiconductor chip and the second semiconductor chip,
wherein the second surface of the first semiconductor chip includes a first region and a second region that do not overlap each other, and the first region vertically overlaps the adhesive layer, and the second region is not covered by the adhesive layer,
the first semiconductor chip further includes a third chip dummy pad and a fourth chip dummy pad disposed on the second region,
the first semiconductor chip further includes a third corner at a first end of the first chip edge and a fourth corner at a second end of the first chip edge, and
each of the third chip dummy pad and the fourth chip dummy pad is disposed at one of the third corner and the fourth corner.

15. The semiconductor package of claim 14, wherein a distance between the third corner and the first corner is shorter than a distance between the fourth corner and the first corner, and
the third chip dummy pad is disposed at the third corner and the fourth chip dummy pad is disposed at the fourth corner,
the semiconductor package further comprising at least one third bump ball on the third chip dummy pad and at least one fourth bump ball on the fourth chip dummy pad.

16. The semiconductor package of claim 15, wherein the first bump ball and the third bump ball are connected to each other through a second wire, and the second bump ball and the fourth bump ball are connected to each other through a third wire.

17. A semiconductor package comprising:
a package substrate including first and second surfaces opposite to each other in a first direction and a plurality of substrate pads on the second surface;
a first semiconductor chip on the package substrate, including third and fourth surfaces opposite to each other in the first direction, and including a plurality of first chip pads and a plurality of first chip dummy pads on the fourth surface;
a plurality of first wires with each first wire of the plurality of first wires respectively connecting a respective substrate pad of the plurality of substrate pads with a respective first chip pad of the plurality of first chip pads;
a second semiconductor chip on the first semiconductor chip, including fifth and sixth surfaces opposite to each other in the first direction and a plurality of second chip pads and a plurality of second chip dummy pads on the sixth surface; and
a plurality of second wires with each second wire of the plurality of second wires respectively connecting a respective first chip pad of the plurality of first chip pads with a respective second chip pad of the plurality of second chip pads,
wherein the first semiconductor chip includes first and second chip edges respectively extending in a second direction intersecting the first direction and spaced apart from each other in a third direction intersecting the first direction and the second direction, third and fourth chip edges respectively extending in the third direction and spaced apart from each other in the second direction, a first corner formed at the intersection of the first chip edge and the third chip edge, a second corner formed at the intersection of the first chip edge and the fourth chip edge, a third corner formed at the intersection of the second chip edge and the fourth chip edge, and a fourth corner formed at the intersection of the second chip edge and the third chip edge,
the second semiconductor chip includes fifth and sixth chip edges respectively extending in the second direction and spaced apart from each other in the third direction, seventh and eighth chip edges respectively extending in the third direction and spaced apart from each other in the third direction, a fifth corner formed at the intersection of the fifth chip edge and the seventh chip edge, a sixth corner formed at the intersection of the fifth chip edge and the eighth chip edge, a seventh corner formed at the intersection of the sixth chip edge and the eighth chip edge, and an eighth corner formed at the intersection of the sixth chip edge and the seventh chip edge,
each chip dummy pad of the plurality of first chip dummy pads is disposed at one of the first to fourth corners, and
each chip dummy pad of the plurality of second chip dummy pads is disposed at one of the fifth to eighth corners.

18. The semiconductor package of claim 17, wherein the sixth surface of the second semiconductor chip includes a first region and a second region that do not overlap each other,
the first region vertically overlaps the first semiconductor chip,
the second region does not vertically overlap the first semiconductor chip,
the plurality of second chip pads is disposed in the second region, and
the plurality of second chip dummy pads is disposed in the first region.

19. The semiconductor package of claim 17, wherein the plurality of first chip dummy pads includes a first chip dummy pad and a second chip dummy pad, and
the first chip dummy pad is disposed at a first end of the first chip edge and the second chip dummy pad is disposed at a second end of the first chip edge with the plurality of first chip pads interposed therebetween along the first chip edge,
the semiconductor package further comprising a first bump ball on the first chip dummy pad and a second bump ball on the second chip dummy pad.

20. The semiconductor package of claim 19, wherein a length of each first chip pad of the plurality of first chip pads in the second direction is less than the length of the first chip dummy pad in the second direction,
a length of each of the plurality of first chip pads in the third direction is less than a length of the first chip dummy pad in the third direction.
